(19) United States
(12) Patent Application Publication
(10) Pub. No.: US 2019/0203352 A1
(43) Pub. Date: Jul. 4, 2019

(54) METHOD OF FORMING ORGANIC FILM

(71) Applicant: FLOSFIA INC., Kyoto (JP)

(72) Inventors: Shigetaka KATORI, Okayama (JP); Takashi SHINOHE, Kyoto (JP); Takuto IGAWA, Kyoto (JP)

(21) Appl. No.: 16/235,084

(22) Filed: Dec. 28, 2018

(30) Foreign Application Priority Data
Dec. 29, 2017 (JP) 2017-255171

(51) Int. Cl. C23C 16/448; C09D 147/00; C23C 16/46; C03C 17/32

(52) U.S. Cl. CPC C23C 16/4486; C09D 147/00; C03C 2218/1525; C03C 17/32; C23C 16/46

(57) ABSTRACT

In a first aspect of a present inventive subject matter, a method of forming an organic film includes preparing a raw material solution containing an organic compound and a solvent with a boiling point that is 150° C. or higher; generating atomized droplets by atomizing the raw material solution containing the organic compound and the solvent with the boiling point that is 150° C. or higher; carrying the atomized droplets onto a base; and causing thermal reaction of the atomized droplets adjacent to the base at a temperature that is the boiling point of the solvent or at a higher temperature than the boiling point of the solvent contained in the raw material solution to form an organic film on the base.

### CROSS-REFERENCE TO RELATED APPLICATION

This application is a new U.S. patent application that claims priority benefit of Japanese patent application No. 2017-2551711 filed on Dec. 29, 2017, the disclosures of which are incorporated herein by reference in its entirety.

### BACKGROUND OF THE INVENTION

### Field of the Invention

The present disclosure relates to a method of forming an organic film using a raw material solution.

### DESCRIPTION OF THE RELATED ART

Recently, organic films are studied to be used in next-generation electronic devices instead of inorganic films, because organic films are able to be formed by comparatively cost-effective methods such as coating and printing. Also, it is possible to realize flexible and foldable organic devices making use of flexibility of organic films. An electroluminescence (EL) using luminous organic compound for image elements may be listed as an example of an electronic device using an organic film. For more details, an organic EL element is a current-driven element including an organic film, a first electrode arranged at a first side of the organic film and a second electrode arranged at a second side of the organic film, and the organic EL element is configured to emit light through the organic film by applying current to the first electrode and the second electrode such that electrons and holes injected in the organic film from the first electrode and the second electrode are reconnected to emit light. Accordingly, organic films used in electronic devices are required to have thermal stability.

As methods of forming an organic film, there are a dry process typified by a vacuum deposition method and a wet process typified by a spin coating method. As advantages of the dry process, film thickness is easily adjustable, and laminating layers of different materials and selectively forming a film using a mask with an opening are possible. However, a raw material that is a polymeric material and a thermally unstable material are unavailable for the dry process. Also, film-formation apparatus for the dry process tends to be large and to increase cost. As advantages of the wet process, the polymeric material and the thermally unstable material are available for the wet process, film-formation apparatus for the wet process tends to be compact and suitable for mass production. However, laminating layers of different materials and selectively forming a film using a mask with an opening are difficult in the wet process, and also, the wet process requires flatness of a substrate on which a film is to be formed.

It is open to the public that a method of forming an organic thin film for an organic electroluminescence (EL) element, and a device of forming the organic thin film, that is applicable to film-formation using as a raw material that is a polymeric material or an organic material unstable to heat. The method includes turning a raw liquid with an organic material dissolved or dispersed in a solvent into aerosol, and fine particles of the organic material formed by vaporizing a solvent in the aerosol are blown on to a substrate to form a thin film of the organic material on the substrate (For reference, see Japanese Unexamined Patent Application Publication No. JP2002-075641A). However, the fine particles of the organic material are collided on the substrate when being blown on to the substrate, and such collision energy of the fine particles tends to affect negatively the quality including thermal stability of a film to be formed on the substrate.

Also, it is open to the public that a method of forming an organic film includes a step of mist formation by spraying an organic film composition including a solvent and an organic material that is dissolved or dispersed in the solvent from a nozzle of a mist forming means into carrier gas to form a mist, a step of heating the mist by a heating means, projecting the heated mist through a projection nozzle onto a substrate to deposit the mist on the substrate, and drying the deposited mist on the substrate (For reference, see Japanese Unexamined Patent Application Publication No. JP2005-158954A). However, an organic film to be formed by the method disclosed in this method tends to be lacking in sufficient flatness and adhesiveness onto the substrate. Accordingly, deterioration of the organic film over time under a high temperature environment tends to occur.

### SUMMARY OF THE INVENTION

In a first aspect of a present inventive subject matter, a method of forming an organic film includes preparing a raw material solution that contains an organic compound and a solvent with a boiling point that is 150° C. or higher; generating atomized droplets by atomizing the raw material solution containing the organic compound and the solvent with the boiling point that is 150° C. or higher; carrying the atomized droplets onto a base; and causing thermal reaction of the atomized droplets adjacent to the base at a temperature that is the boiling point of the solvent or at a higher temperature than the boiling point of the solvent contained in the raw material solution to form an organic film on the base.

According to an embodiment of a present inventive subject matter, the solvent that is contained in the raw material solution contains a cyclic compound.

Also, according to an embodiment of a present inventive subject matter, the solvent that is contained in the raw material solution contains a heterocyclic compound.

Furthermore, according to an embodiment of a present inventive subject matter, it is suggested that the boiling point of the solvent contained in the raw material solution is 200° C. or higher.

It is suggested that the organic compound contains a macromolecular compound.

Furthermore, it is suggested that the macromolecular compound contained in the organic compound is a conjugated compound.

According to an embodiment of a present inventive subject matter, the causing thermal reaction of the atomized droplets adjacent to the base is done at 240° C. or higher.

Also, according to an embodiment of a present inventive subject matter, the generating atomized droplets by atomizing the raw material solution is done using ultrasonic vibration.

Furthermore, according to an embodiment of a present inventive subject matter, the causing thermal reaction of the atomized droplets is done under atmospheric pressure.

Also, it is suggested that the causing thermal reaction of the atomized droplets is done under atmospheric pressure.

Furthermore, it is suggested that the carrying the atomized droplets onto the base is done by supplying carrier gas to the atomized droplets.

Also, it is suggested that the causing thermal reaction of the atomized droplets adjacent to the base to form the organic film on the base is conducted by heating the base to the temperature that is the boiling point of the solvent or to the higher temperature than the boiling point of the solvent.

In a second aspect of a present inventive subject matter, a method of forming an organic film includes preparing a raw material solution containing an organic compound and a solvent with a boiling point that is in a range of 150° C. to 350° C.; generating atomized droplets by atomizing the raw material solution containing the organic compound and the solvent with the boiling point that is in the range of 150′C to 350° C.; supplying carrier gas to the atomized droplets to carry the atomized droplets onto a base; and heating the base to have a temperature higher than the boiling point of the solvent contained in the raw material solution to cause thermal reaction of the atomized droplets adjacent to the base to form an organic film on the base.

Also, it is suggested that the thermal reaction of the atomized droplets adjacent to the base is conducted by heating the base to have the temperature higher than the boiling point of the solvent by 8° C. or more according to an embodiment of a method of a present inventive subject matter.

Furthermore, it is suggested that the solvent that is contained in the raw material solution contains a cyclic compound.

According to an embodiment of a method of a present inventive subject matter, the solvent that is contained in the raw material solution contains a heterocyclic compound.

Also, it is suggested that the organic compound contains a macromolecular compound.

Furthermore, it is suggested that the macromolecular compound that is contained in the organic compound is a conjugated compound.

It is suggested that the heating the base is conducted by a heater arranged adjacent to the base.

Also, it is suggested that the carrier gas is at least one selected from among oxygen, ozone, nitrogen, argon, hydrogen gas and forming gas and supplied to the atomized droplets at a flow rate that is 0.01 L/minute to 20 L/minute.

Furthermore, it is suggested that the base is a glass substrate.

### BRIEF DESCRIPTION OF THE DRAWING

FIG. 1 shows a schematic diagram of a mist chemical vapor deposition (CVD) apparatus that may be used as a film (layer)-formation apparatus according to an embodiment of a method of a present inventive subject matter.

FIG. 2 shows a fluorescence spectrum measurement result of an organic film obtained according to an embodiment of a method of a present inventive subject matter and also shows a fluorescence spectrum measurement result of the organic film after four-hour annealing treatment.

FIG. 3 shows a fluorescence spectrum measurement result of an organic film obtained in Comparative Example 2, and also shows fluorescent measurement results of the organic film after four-hour annealing treatment and after eight-hour annealing treatment.

### DETAILED DESCRIPTION OF EMBODIMENTS

The terminology used herein is for the purpose of describing particular embodiments only and is not intended to be limiting of the subject matter. As used herein, the singular forms “a”, “an” and “the” are intended to include the plural forms as well, unless the context clearly indicates otherwise.

As used herein, the term “and/or” includes any and all combinations of one or more of the associated listed items.

According to a present inventive subject matter, a method of forming an organic film includes preparing a raw material solution that contains an organic compound and a solvent with a boiling point that is 150° C. or higher (preparing a raw-material solution). Furthermore, the method of forming the organic film includes generating atomized droplets by atomizing the raw material solution containing the organic compound and the solvent with the boiling point that is 150° C. or higher (generating atomized droplets from a raw-material solution). Also, the method of forming the organic film includes carrying the atomized droplets onto a base (carrying the atomized droplets onto a base). Furthermore, the method of forming the organic film includes causing thermal reaction of the atomized droplets adjacent to the base at a temperature that is the boiling point of the solvent or at a higher temperature than the boiling point of the solvent contained in the raw material solution to form an organic film (forming a film).

(Base)

The base is not particularly limited as long as the base is able to support a film to be directly or indirectly formed on the base. The material of the base (base material) is not particularly limited as long as an object of a present inventive subject matter is not interfered with, and the base may be a known base. Also, the base may contain an organic compound. Also, the base may contain an inorganic compound. Furthermore, the base may have a porous structure.

Also, a base including at least a layer formed on the base may be used as a base according to an embodiment of a method of a present inventive subject matter. Two or more layers may be arranged on the base. The layer may be partly arranged on the base. Also, the layer may be arranged on an entire surface of the base. Examples of a constituent material of the metal layer may contain one or more metals selected from among gallium, iron, indium, aluminum, vanadium, titanium, chromium, rhodium, nickel, cobalt, zinc, magnesium, calcium, silicon, yttrium, strontium, and barium. Examples of a constituent material of the semiconductor layer include a chemical element such as silicon or germanium, a chemical compound containing one or more chemical elements selected from among chemical elements of Group 3 to Group 5 in the periodic table and chemical elements of Group 13 to Group 15 in the periodic table. Examples of a constituent material of the metal oxide containing one or more chemical elements selected from among chemical elements of Group 3 to Group 5 in the periodic table and chemical elements of Group 13 to Group 15 in the periodic table, a metal sulfide containing one or more chemical elements selected from among chemical elements of Group 3 to Group 5 in the periodic table and chemical elements of Group 13 to Group 15 in the periodic table, a metal selenide containing one or more chemical elements selected from among chemical elements of Group 3 to Group 5 in the periodic table and chemical elements of Group 13 to Group 15 in the periodic table, and a metal nitride containing one or more chemical elements selected from among chemical elements of Group 3 to Group 5 in the periodic table and chemical elements of Group 13 to Group 15 in the periodic table. Examples of a constituent material of the electrically-conductive film include tin-doped indium oxide (ITO), fluorine-doped indium oxide (FTO), zinc oxide (ZnO), aluminum doped zinc oxide (AZO), gallium-doped zinc oxide (GZO), tin oxide (SnO₂), indium oxide (In₂O₃), and tungsten oxide (WO₃). According to an embodiment of the present invention, the electrically-conductive film including an electrically-conductive oxide is preferable, and further preferably is a tin-doped indium oxide (ITO) film. Examples of a constituent material of the electrically-insulating film include aluminum oxide (Al₂O₃), titanium oxide (TiO₂), silicon oxide (SiO₂), silicon nitride (Si₃N₄), silicon oxynitride (Si₄O₅N₃).

In forming the metal film, the semiconductor film, the electrically-conductive film, and/or the electrically-insulating film, the method of forming the metal film, the semiconductor film, the electrically-conductive film, and/or the electrically-insulating film is not particularly limited, and a known method may be used. Examples of the method of forming the metal film, the semiconductor film, the electrically-conductive film, and/or the electrically-insulating film include a mist CVD method, a sputtering method, a CVD (Chemical Vapor Deposition) method, an SPD (Spray Pyrolysis Deposition) method, an evaporation method, an ALD (Atomic Layer Deposition) method, and coating methods such as dipping, dropping, a doctor blade coating, ink jet coating, spin coating, brush coating, spray coating, roll coating, air knife coating, curtain coating, wire-bar coating, gravure coating, and inkjet coating.

Variously-shaped bases are available for a base. The base may have a plate shape, a circular plate shape, a shape of fiber, a shape of a stick, a shape of a round pillar, a shape of a square pillar, a shape of a tube, a shape of a spiral, a shape of sphere, and/or a shape of ring. According to an embodiment of a present inventive subject matter, the base may be preferably a substrate. The thickness of the substrate is not particularly limited as long as the substrate is able to support a film to be directly or indirectly formed on the substrate. According to embodiments of a present inventive subject matter, the thickness of the substrate is preferably in a range of 0.5 μm to 100 mm, and further preferably in a range of 1 μm to 10 mm. The substrate may be an electrically-insulating substrate, a semiconductor substrate, a metal substrate, or an electrically-conductive substrate. According to an embodiment of a present inventive subject matter, the base is preferably a glass substrate.

(Generating Atomized Droplets from a Raw Material Solution)

A raw material solution is turned into atomized droplets floating in a space of a container of a generator of atomized droplets. The raw material solution may be turned into atomized droplets by a known method, however, according to an embodiment of a present inventive subject matter, the raw material solution is preferably turned into atomized droplets by use of ultrasonic vibration. Atomized droplets including mist particles, obtained by using ultrasonic vibration and floating in the space have the initial velocity that is zero. Since atomized droplets floating in the space are carriable as gas, the atomized droplets floating in the space are preferable to avoid damage caused by the collision energy of the atomized droplets onto the base without being blown like a spray. The size of droplets is not limited to a particular size, and may be a few mm, however, the size of droplets is preferably 50 μm or less. The size of droplets is further preferably in a range of 100 nm to 10 μm.

(Preparing a Raw-Material Solution)

The raw-material solution is not particularly limited as long as the raw-material solution contains at least an organic compound and a solvent, and atomized droplets are able to be formed from the raw-material solution.

The raw-material solution may contain an organic material and/or an inorganic material as long as an object of a present inventive subject matter is not interfered with.

The organic material is not particularly limited and may be a known organic material. The organic material may be a low-molecular compound or a macromolecular compound, however, the organic material is preferably a macromolecular compound to form an organic film, according to embodiments of a present inventive subject matter. The term “macromolecular” herein means a chemical compound with a molecular weight that is 10000 or more. Also, the term “low-molecular compound” herein means a chemical compound with a molecular weight that is less than 10000. Examples of the low-molecular compound includes a polyacene compound, phenanthrene, picene, flumilene, pyrene, anthanthrene, peropyrene, a coronene compound, a perylene compound, a tetrathiafulvalene compound, a quinone compound, a tetracyanoquinodimethane compound, trinaphthene, heptaphene, ovalene, rubicene, violanthrone, isoviolanthrone, chrysene, circum anthracene, bisanthene, zethrene, heptazethrene, pyranthrene, violanthene, isoviolanthene, biphenyl, triphenylene, terphenyl, quaterphenyl, circobiphenyl, kekulene, phthalocyanine, porphyrin, fullerenes (C60, C70), oligomers of polythiophene, oligomers of polypyrrole, oligomers of polyphenylene, oligomers of polyphenylenevinylene, oligomers of polythyenylenevinylene, copolymeric oligomers of thiophene and phenylene, copolymeric oligomers of thiophene and fluorene and derivatives thereof.

Examples of the polyacene compound include anthracene, naphthalene, pyrene, naphthacene, tetracene, pentacene, benzopentacene, dibenzopentacene, tetrabenzopentacene, naphtha pentacene, hexacene, heptacene, and nanoacene. Examples of the coronene compound include coronene, benzocoronene, dibenzocoronene, hexabenzocoroncne, benzodicoronene and vinylcoronene. Examples of the perylene compound include perylene, terylene, diperylene and quaterrylene.

Examples of the macromolecular compound include a conjugated macromolecular compound and an unconjugated macromolecular compound. Examples of the conjugated macromolecular compound include a polythiophene-based compound, a polypyrrole-based compound, a polyindole-based compound, a polycarbazole-based compound, a polyaniline-based compound, a polyacetylene-based compound, a polyfuran-based compound, a polyparaphenylene vinylene-based compound, a polyazulene-based compound, a polyparaphenylene-based compound, a polyphenylene sulfide, a polyisothianaphthene-based compound, a polythiazyl-based compound, and a derivative of at least one selected from the above mentioned examples of the conjugated macromolecular compound. Examples of the unconjugated macromolecular compound include polyethylene, polyvinyl chloride, polycarbonate, polystyrene, polymethyl methacrylate, polybutyl methacrylate, polyester, polysulfone, polyphenylene oxide, polybutadiene, poly (N-vinylcarbazole), hydrocarbon resin, ketone resin, phenoxy resin, polyamide, ethyl cellulose, vinyl acetate, acrylonitrile-butadiene-styrene (ABS) resin, polyurethane, melamine resin, unsaturated polyester resin, alkyd resin, epoxy resin, silicon resin. According to embodiments of a present inventive subject matter, the macromolecular compound is preferably a conjugated macromolecular compound, and further preferably a polyparaphenylene vinylene-based compound. Examples of the polyparaphenylene vinylene-based compound include poly(2,5-dialkoxy-para-phenylenevinylene)RO-PPV), cyano-substituted-poly(para-phenylene-vinylene)(CN-PPV), poly(2-dimethyloctylsilyl-para-phenylenevinylene) (DMOA-PPV), and poly(2-methoxy-5-(2′-ethylhexyloxy)-para-phenylenevinylene) (MEH-PPV).

The mixing ratio of the organic compound in the raw material solution is not particularly limited, however, preferably in a range of 0.001 weight % (wt %) to 80 wt %, and further preferably in a range of 0.01 wt % to 80 wt %.

The solvent is not particularly limited as long as the solvent has a boiling point that is 150° C. or higher. Accordingly, the solvent may be preferably a cyclic compound or a heterocyclic compound, however, the solvent is further preferably a cyclic compound to obtain a raw material solution from which atomized droplets are suitably generated. Also, according to embodiments of a present inventive subject matter, the solvent is further preferably a polycyclic compound.

According to embodiments of a method of a present inventive subject matter, the boiling point of the solvent is preferably 180° C. or higher to obtain organic films that are more thermally stable, and the boiling point of the solvent is further preferably 200° C. or higher. The upper limit of the boiling point of the solvent is not particularly limited, however, according to embodiments of the method of the present inventive subject matter, the boiling point of the solvent is preferably 300° C. or less, and further preferably 250° C. or less. The term “boiling point” herein means a boiling point under atmospheric pressure.

The cyclic compound is not particularly limited, however, preferable examples of the cyclic compound include an aromatic hydrocarbon, an aromatic alcohol, and a heterocyclic compound according to embodiments of a present inventive subject matter. Examples of the heterocyclic compound include a cyclic ester compound, a cyclic amide compound, and a cyclic ketone compound. Examples of the aromatic hydrocarbon include trimethylbenzene, ethyl toluene, ethyl xylene, diethyl benzene, alkylbenzene including propyl benzene, methyl naphthalene such as 1-methyl naphthalene, ethyl naphthalene, alkyl naphthalene including dimethyl naphthalene, tetralin, alkyl biphenyl, and alkyl anthracene. Examples of the aromatic alcohol include benzyl alcohol, o-tolyl methanol, m-tolyl methanol, p-tolyl methanol, 1-phenyl ethanol, 2-phenyl ethanol, 1-phenyl-1 propanol, 1-phenyl-2 propanol, 3-phenyl-1 propanol. Examples of the cyclic ester compound include four-membered β-lactone, five-membered γ-lactone, six-membered δ-lactone and seven-membered ε-lactone. For more details, examples of the cyclic ester include β-butyrolactone, γ-butyrolactone, γ-valerolactone, γ-hexalactone, γ-heptalactone, γ-octalactone, γ-nonalactone, γ-decalactone, γ-undecalactone, δ-valerolactone, δ-hexalactone, S-heptalactone, δ-octalactone, δ-nonalactone, δ-decalactone. δ-undecalactone, and ε-caprolactone. Examples of the cyclic amide compound include four-membered β-lactam, five-membered γ-lactam, six-membered δ-lactam and seven-membered ε-lactam. For more details, examples of the cyclic ester include β-butyrolactam, γ-butyrolactam, γ-valcrolactam, γ-hexalactam, γ-heptalactam, γ-octalactam, γ-nonalactam, γ-decalactam γ-undecalactam, δ-valerolactam, δ-hexalactam, δ-heptalactam, δ-octalactam, δ-nonalactam, δ-decalactam, δ-undecalactam, and ε-caprolactam, N-Methyl-2-pyrrolidone, N-Ethyl-2-pyrrolidone, N-Propyl-2-pyrrolidone, and N-Octhyl-2-pyrrolidone. Examples of the cyclic ketene compound include cyclohexanon, cycloheptanone, cyclooctanone, cyclononanone, and cyclodecanone. According to embodiments of a present inventive subject matter, the solvent is preferably a heterocyclic compound, and the solvent is further preferably a cyclic ester compound or a cyclic amide compound. According to an embodiment of a present inventive subject matter, the solvent is most preferably a cyclic amide compound.

The mixing ratio of the solvent in the raw materials is not particularly limited, however, preferably in a range of 0.001 mol % to 99 mol %, and further preferably in a range of 0.01 mol % to 99 mol %.

The raw material solution may further contain an additive. The additive is not particularly limited as long as an object of a present inventive subject matter is not interfered with. The additive may be an acid, an alkali, and/or a solvent, and the additive may be a known additive. The additive may be an inorganic additive or may be an organic additive. Examples of the acid include hydrofluoric acid, hydrochloric acid, hydrobromic acid, hydroiodic acid, sulfuric acid, phosphoric acid, nitric acid, acetic acid, carbonate acid, formic acid, benzoic acid, chlorite, hypochlorite, sulfite, next sulfite, phosphorous acid, proton acid including hypophosphorous acid, and a mixture of two or more thereof. Also, examples of the alkali include sodium hydroxide, potassium hydroxide, calcium hydroxide, and a mixture of two or more thereof. The solvent is not particularly limited as long as an object of a present inventive subject matter is not interfered with, and the solvent may be an organic solvent, an inorganic solvent such as water, or may be a mixture of an organic solvent and an inorganic solvent. Examples of the organic solvent include an alcohol, an ester, and an ether. Examples of water include pure water, ultrapure water, tap water, well water, mineral spring water, mineral water, hot spring water, spring water, fresh water, and seawater.

(Carrying the Atomized Droplets onto a Base)

Atomized droplets floating in the space of a container for forming atomized droplets are carried onto a base by carrier gas. The carrier gas is not particularly limited as long as an object of the present inventive subject matter is not interfered with, and thus, examples of the carrier gas include an oxidizing gas, an inert gas, and a reducing gas. Examples of the oxidizing gas include oxygen and ozone. Examples of the inert gas include nitrogen and argon. Also, examples of the reducing gas include a hydrogen gas and a forming gas. The type of carrier gas may be one or more, and a dilution gas at a reduced flow rate (e.g., 10-fold dilution gas) may be used further as a second carrier gas. The carrier gas may be supplied from one or more locations. The flow rate of the carrier gas is not particularly limited, however, the flow rate of the carrier gas may be in a range of 0.01 to 20 L/min. According to an embodiment of a present inventive subject matter, the flow rate of the carrier gas may be preferably in a range of 1 to 10 L/min. When a dilution gas is used, the flow rate of the dilution gas is preferably in a range of 0.001 to 2 L/min. According to an embodiment of a present inventive subject matter, when a dilution is used, the flow rate of the dilution gas is further preferably in a range of 0.1 to 1 L/min.

(Forming a Film)

The atomized droplets carried onto the base by the carrier gas are thermally reacted (through “thermal reaction”) to form an organic film on the base. Herein, “thermal reaction” works as long as the atomized droplets react by heat, and conditions of reaction are not particularly limited as long as an object of a present inventive subject matter is not interfered with. In embodiments of a present inventive subject matter, the thermal reaction is not particularly limited as long as the thermal reaction is conducted at a temperature that is a boiling point of the solvent or at a temperature that is higher than the boiling point of the solvent, however, the thermal reaction is preferably conducted at a temperature that is 210° C. or higher to enhance thermal stability of a film to be obtained, and is further preferably conducted at a temperature that is 240° C. or higher. Furthermore, according to embodiments of a method of a present inventive subject matter, the thermal reaction is preferably conducted at a temperature that is higher than the boiling point of the solvent by 8° C. or more for a better film-formation, and is further preferably conducted at a temperature that is higher than the boiling point of the solvent by 30° C. or more. Also, the upper limit of the temperature for the thermal reaction is not particularly limited, however, the thermal reaction is preferably conducted at 350° C. or less. According to an embodiment of a method of a present inventive subject matter, a method of forming an organic film includes preparing a raw material solution that contains an organic compound and a solvent with a boiling point that is in a range of 150° C. to 350° C.; generating atomized droplets by atomizing the raw material solution that contains the organic compound and the solvent with the boiling point that is in the range of 150° C. to 350° C.; supplying carrier gas to the atomized droplets to carry the atomized droplets onto a base; and heating the base to have a temperature higher than the boiling point of the solvent contained in the raw material solution to cause thermal reaction of the atomized droplets adjacent to the base to form an organic film on the base. Also, according to an embodiment of a method of a present inventive subject matter, the thermal reaction may be further preferably conducted at 300° C. or less. The temperature of a base is adjusted by a heater adjacently arranged on the base, on which a film is formed, and the temperature of the thermal reaction includes a temperature of the base when a film starts to be formed on the base. Also, the base may be arranged directly or indirectly on the heater.

Also, the thermal reaction may be conducted in any environment such as in a vacuum environment, in a non-oxygen atmosphere, in a reducing-gas atmosphere, or in an oxygen atmosphere, however, the thermal reaction is preferably conducted in a non-oxygen atmosphere or in an oxygen atmosphere. Furthermore, the thermal reaction may be conducted under atmospheric pressure, under increased pressure or under decreased pressure, however, according to embodiments of a present inventive subject matter, the thermal reaction is preferably conducted under atmospheric pressure. The film thickness of an organic film to be obtained is easily adjusted by changing a film-formation time.

If a film (layer)-formation apparatus with a linear nozzle, through which the atomized droplets are supplied to the base, is used, the film thickness of an organic film to be formed on the base is adjusted by changing the number of passages of the linear nozzle of the film-formation apparatus on or above the base. The linear nozzle of the film-formation apparatus may move over a base to supply the atomized droplets to the base. Also, the linear nozzle of the film-formation apparatus may be fixed at a position and a base is on a conveyor belt to pass the base under the linear nozzle of the film-formation apparatus, for example. Furthermore, two or more linear nozzles of the film-formation apparatus may be arranged. Also, roll to roll processing techniques may be used to form an organic film, according to an embodiment of a present inventive subject matter.

According to an embodiment of a method of the present inventive subject matter, the method may further include an annealing treatment of the organic film. For example, a method of forming an organic film as an embodiment includes preparing a raw material solution containing an organic compound and a solvent with a boiling point that is in a range of 150° C. to 350° C.; generating atomized droplets by atomizing the raw material solution containing the organic compound and the solvent with the boiling point that is in the range of 150° C. to 350° C.; supplying carrier gas to the atomized droplets to carry the atomized droplets onto a base; and heating the base to have a temperature higher than the boiling point of the solvent contained in the raw material solution to cause thermal reaction of the atomized droplets adjacent to the base to form an organic film on the base. The method of forming the organic film may further includes annealing the organic film at a temperature that is in a range of 50° C. to 650° C. Annealing the organic film at a temperature that is in a range of 100° C. to 300° C. may be further preferable. Also, annealing time is basically in a range of one minute to 48 hours. According to an embodiment of a present inventive subject matter, annealing time is preferably in a range of ten minutes to 24 hours, and further preferably in a range of 30 minutes to 12 hours.

According to an embodiment of a present inventive subject matter, an organic film may be formed directly on the base. Also, an organic film may be formed indirectly on the base, on which one or more layers may be formed, and the organic film may be formed on the one or more layers arranged on the base. Examples of the one or more layers include a buffer layer and/or a stress-relief layer. The buffer layer and/or the stress-relief layer may be formed by a known method, however, according to an embodiment of a present inventive subject matter, the buffer layer and/or the stress-relief layer are preferably formed by mist CVD apparatus and/or by use of a mist deposition method.

Organic films that are formed as mentioned above are obtained with thermal stability, and deterioration of the organic films over time under a high temperature environment is expected to be suppressed. Accordingly, it is possible to form organic films industrially advantageously.

Embodiments are explained in more details.

### Practical Example 1

1. Film (Layer)-Formation Apparatus

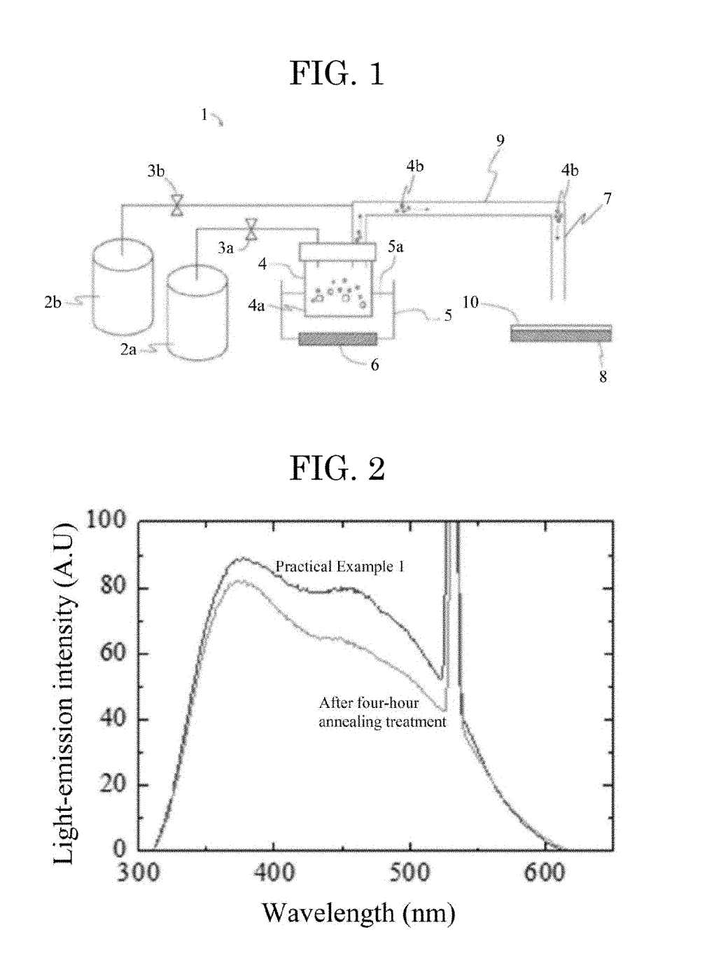

FIG. 1 shows a mist chemical vapor deposition (CVD) apparatus 1 used in practical examples and comparative examples to form an organic film (layer). The mist CVD apparatus 1 includes a carrier gas supply device 2a, a first flow-control valve 3a to control a flow of a carrier gas that is configured to be sent from the carrier gas supply device 2a, a diluted carrier gas supply device 2b, a second flow-control valve 3b to control a flow of a carrier gas that is configured to be sent from the diluted carrier gas supply device 2b, an atomized droplets (including mist) generator 4 in that a raw material solution 4a is contained, a vessel 5 in that water 5a is contained, and an ultrasonic transducer 6 that may be attached to a bottom surface of the vessel 5. The mist CVD apparatus 1 further includes a hot plate 8 on that a base 10 is placed. The mist CVD apparatus 1 further includes a supply tube 9 at a first end connected to the atomized droplets generator 4 to supply the atomized droplets carried by carrier gas onto the base 10 at a second end of the supply tube 9. The second end of the supply tube 9 with a nozzle 7 is positioned adjacent to the base 10 placed on the hot plate 8.

2. Preparation of Raw-Material Solution

A raw-material solution was prepared by mixing 2-methoxy, 5-(2′ethylhexyloxy)-para-phenylene vinylene (MEH-PPV) in N-methyl-2-pyrrolidone with a boiling point that is 202° C.

3. Film (Layer) Formation Preparation

The raw-material solution 4a obtained at 2. the Preparation of the Raw-Material Solution above was set in the container of the atomized droplets generator 4. Also, a glass/ITO substrate as a base 10 was placed on the hot plate 8. The hot plate 8 was activated to raise the temperature of the base 10 up to 240° C. The first flow-control valve 3a and the second flow-control valve 3b were opened to supply carrier gas from the carrier gas device 2a and the diluted carrier gas device 2b. The flow rate of the carrier gas from the carrier gas source 2a was set at 4.0 L/min, and the diluted carrier gas from the diluted carrier gas source 22b was set at 4.0 L/min. In this embodiment, nitrogen was used as the carrier gas.

4. Formation of an Organic Film

The ultrasonic transducer 6 was then activated to vibrate at 2.4 MHz. and vibrations were propagated through the water 5a in the vessel 5 to the raw material solution 4a to turn the raw material solution 4a into atomized droplets 4b. The atomized droplets 4b were carried through a supply pipe 9 by the carrier gas onto the base 10, and the atomized droplets 4b heated and thermally reacted adjacent to the base 10 at 240° C. under atmospheric pressure to be an organic film on the base 10.

5. Evaluation

A fluorescence spectrum measurement was conducted on the organic film obtained at 4. the Formation of an organic film above, and the line graph at Practical Example 1 in FIG. 2 shows the result. As shown in FIG. 2, the organic film had a light emission peak in a wavelength range of 350 nm to 400 nm.

Evaluation of Thermal Stability of the Organic Film

The organic film obtained at 4. the Formation of an organic film above was annealed at 240° C. for four hours and a fluorescence spectrum measurement was conducted on the organic film after the four-hour annealing treatment, and the line graph at After four-hour annealing treatment in FIG. 2 shows the result. As shown in FIG. 2, the organic film even after the four-hour annealing treatment had a light emission peak in a wavelength range of 350 nm to 400 nm, that is the same as the light emission peak of the organic film before the annealing treatment shown at the line graph at Practical Example 1 of FIG. 2. Also, FIG. 2 shows that peak positions and light-emission intensity of fluorescence spectrum of the organic film were maintained even after the annealing treatment. Furthermore, the organic film was annealed for eight hours, and the evaluation result of the organic film was almost the same as the result of the organic film after the four-hour annealing treatment. Accordingly, it was found that the organic film obtained according to an embodiment of a present inventive subject matter maintains thermal stability through annealing treatment(s).

### Practical Example 2

As Practical Example 2, an organic film was obtained under the same conditions as the conditions in the Practical Example 1 except one condition that the hot plate was activated to raise the temperature of the base up to 210° C. instead of 240° C. Also, a fluorescence spectrum measurement was conducted on the organic film obtained at this Practical Example 2. As a result, the organic film obtained at the Practical Example 2 had enhanced light emission properties and a light emission peak in a wavelength range of 350 nm to 400 nm, that is the same as the light emission peak of the organic film obtained at Practical Example 1. Also, thermal stability of the organic film obtained at the Practical Example 2 was evaluated in the same evaluation way as the evaluation way used for the organic film obtained at Practical Example 1. Accordingly, it was found that the organic film obtained at the Practical Example 2 maintains thermal stability through annealing treatment(s).

### Comparative Example 1

As Comparative Example 1, an organic film was obtained under the same conditions as the conditions in Practical Example 1 except one condition that toluene with a boiling point that is 110.6° C. was used as a solvent instead of using N-methyl-2-pyrrolidone with a boiling point that is 202° C. Also, a fluorescence spectrum measurement was conducted on the organic film obtained at this Comparative Example 1. As a result, the organic film obtained at the Comparative Example 1 had a low light emission peak that is one fifth or less of the light emission peak of the organic film obtained at the Practical Example 1.

### Comparative Example 2

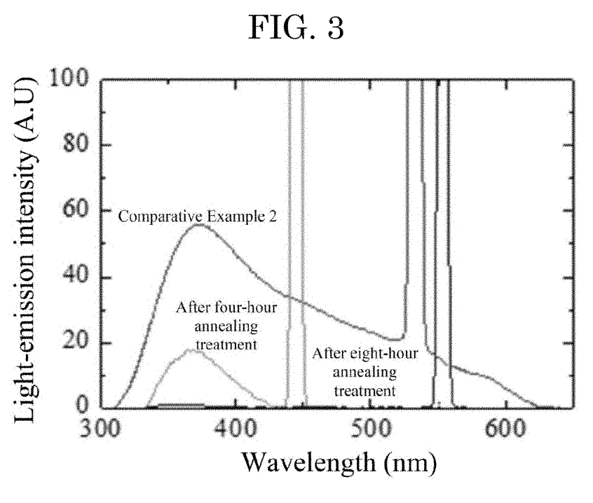

As Comparative Example 2, an organic film was obtained under the same conditions as the conditions in Practical Example 1 except one condition that the hot plate was activated to raise the temperature of the base up to 180° C. to cause thermal reaction of atomized droplets to form an organic film on a base. Also, a fluorescence spectrum measurement was conducted on the organic film obtained at this Comparative Example 2 under the same measurement conditions as the conditions of the fluorescence spectrum measurement that was conducted in Practical Example 1. FIG. 3 shows the result, and the organic film obtained at the Comparative Example 2 had a light emission peak in a wavelength range of 350 nm to 400 nm. Also, thermal stability of the organic film obtained at the Comparative Example 2 was evaluated under the same evaluation conditions as the evaluation conditions used to evaluate the organic film obtained at Practical Example 1, and FIG. 3 shows the results. FIG. 3 shows that the light emission peak of the organic film obtained at this Comparative Example 2 decreased to be one third of the light emission peak after four-hour annealing treatment and disappeared after eight-hour annealing treatment. Accordingly, as a condition, causing thermal reaction of the atomized droplets adjacent to the base at a temperature that is lower than the boiling point of a solvent tends to affect thermal stability of an organic film to be obtained negatively.

According to a method of a present inventive subject matter, it is possible to obtain an organic film with thermal stability. Also, organic films obtained by the method are applicable to various devices and/or fields using organic films. For example, an organic film obtained by the method of a present inventive subject matter is able to be used in organic light-emitting element.

Furthermore, while certain embodiments of the present inventive subject matter have been illustrated with reference to specific combinations of elements, various other combinations may also be provided without departing from the teachings of the present inventive subject matter. Thus, the present inventive subject matter should not be construed as being limited to the particular exemplary embodiments described herein and illustrated in the Figures, but may also encompass combinations of elements of the various illustrated embodiments.

Many alterations and modifications may be made by those having ordinary skill in the art, given the benefit of the present disclosure, without departing from the spirit and scope of the inventive subject matter. Therefore, it must be understood that the illustrated embodiments have been set forth only for the purposes of example, and that it should not be taken as limiting the inventive subject matter as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive subject matter.

### REFERENCE NUMBER DESCRIPTION

1a film (layer)-formation apparatus
2a a carrier gas supply device
2b a diluted carrier gas supply device
3a a flow-control valve of carrier gas
3b a flow-control valve of diluted carrier gas
4a a generator of atomized droplets
4a a raw material solution
4b an atomized droplet
5 a vessel
5a water
6 an ultrasonic transducer
7 a nozzle
8 a hot plate
9 a supply tube
10 a base

What is claimed is:

1. A method of forming an organic film comprising:
preparing a raw material solution comprising an organic compound and a solvent with a boiling point that is 150° C. or higher;
generating atomized droplets by atomizing the raw material solution comprising the organic compound and the solvent with the boiling point that is 150° C. or higher, carrying the atomized droplets onto a base; and
causing thermal reaction of the atomized droplets adjacent to the base at a temperature that is the boiling point of the solvent or at a higher temperature than the boiling point of the solvent comprised in the raw material solution to form an organic film on the base.

2. The method of claim 1, wherein
the solvent comprised in the raw material solution comprises a cyclic compound.

3. The method of claim 1, wherein
the solvent comprised in the raw material solution comprises a heterocyclic compound.

4. The method of claim 1, wherein
the boiling point of the solvent comprised in the raw material solution is 200° C. or higher.

5. The method of claim 1, wherein
the organic compound comprises a macromolecular compound.

6. The method of claim 5, wherein
the macromolecular compound comprised in the organic compound is a conjugated compound.

7. The method of claim 1, wherein
the causing thermal reaction of the atomized droplets adjacent to the base is done at 240° C. or higher.

8. The method of claim 1, wherein
the generating atomized droplets by atomizing the raw material solution is done using ultrasonic vibration.

9. The method of claim 1, wherein
the causing thermal reaction of the atomized droplets is done under atmospheric pressure.

10. The method of claim 1, wherein
the carrying the atomized droplets onto the base is done by supplying carrier gas to the atomized droplets.

11. The method of claim 1, wherein
the causing thermal reaction of the atomized droplets adjacent to the base to form the organic film on the base is conducted by heating the base to the temperature that is the boiling point of the solvent or to the higher temperature than the boiling point of the solvent.

12. A method of forming an organic film comprising:
preparing a raw material solution comprising an organic compound and a solvent with a boiling point that is in a range of 150° C. to 350° C.;
generating atomized droplets by atomizing the raw material solution comprising the organic compound and the solvent with the boiling point that is in the range of 150° C. to 350° C.;
supplying carrier gas to the atomized droplets to carry the atomized droplets onto a base; and
heating the base to have a temperature higher than the boiling point of the solvent comprised in the raw material solution to cause thermal reaction of the atomized droplets adjacent to the base to form an organic film on the base.

13. The method of claim 12, wherein
the thermal reaction of the atomized droplets adjacent to the base is conducted by heating the base to have the temperature higher than the boiling point of the solvent by 8° C. or more.

14. The method of claim 12, wherein
the solvent comprised in the raw material solution comprises a cyclic compound.

15. The method of claim 12, wherein
the solvent comprised in the raw material solution comprises a heterocyclic compound.

16. The method of claim 12, wherein
the organic compound comprises a macromolecular compound.

17. The method of claim 16, wherein
the macromolecular compound comprised in the organic compound is a conjugated compound.

18. The method of claim 12, wherein
the heating the base is conducted by a heater arranged adjacent to the base.

19. The method of claim 12, wherein
the carrier gas is at least one selected from among oxygen, ozone, nitrogen, argon, hydrogen gas and forming gas and supplied to the atomized droplets at a flow rate that is 0.01 L/minute to 20 L/minute.

20. The method of claim 12, wherein
the base is a glass substrate.
